(19) United States
(12) Patent Application Publication
(10) Pub. No.: US 2025/0292815 A1
(43) Pub. Date: Sep. 18, 2025

(54) ANTI-FUSE AND FUSE IN MAGNETORESISTIVE DEVICE

(71) Applicant: Everspin Technologies, Inc., Chandler, AZ (US)

(72) Inventors: Sumio IKEGAWA, Phoenix, AZ (US); Mark DEHERRERA, Chandler, AZ (US); Syed M. ALAM, Austin, TX (US); Frederick B. MANCOFF, Chandler, AZ (US); Kerry Joseph NAGEL, Scottsdale, AZ (US); Michael A. SADD, Austin, TX (US); Jacob T. WILLIAMS, Austin, TX (US); Haifeng XU, Chandler, AZ (US); Xiaohu ZHANG, Chandler, AZ (US)

(73) Assignee: Everspin Technologies, Inc., Chandler, AZ (US)

(21) Appl. No.: 19/077,580

(22) Filed: Mar. 12, 2025

Related U.S. Application Data
(60) Provisional application No. 63/565,964, filed on Mar. 15, 2024.

(51) Int. Cl. G11C 11/16; G11C 17/16; G11C 17/18; H10B 20/25; H10N 50/10; H10N 50/85

(52) U.S. Cl. CPC G11C 11/161; G11C 11/1673; G11C 11/1675; G11C 17/16; G11C 17/18; H10B 20/25; H10N 50/10; H10N 50/85

(57) ABSTRACT

A magnetoresistive memory may include a plurality of magnetoresistive memory devices, wherein each magnetoresistive device includes a fixed magnetic region, a free magnetic region, and an intermediate region disposed between the fixed and free magnetic regions. The magnetoresistive memory may include a spin-orbit-torque (SOT) channel, wherein the SOT channel is in contact with the free magnetic regions of the plurality of magnetoresistive memory devices. The magnetoresistive memory may include a write circuit configured to apply a write current through at least one magnetoresistive memory device of the plurality of magnetoresistive memory devices and the SOT channel, wherein the write current is configured to generate a short in at least one magnetoresistive memory device as a one-time programmable read-only memory (ROM) function.

### CROSS-REFERENCE TO RELATED APPLICATION

This application claims benefit to U.S. Provisional Patent Application No. 63/565,964 filed Mar. 15, 2024, the entire contents of which are incorporated herein by reference.

### TECHNICAL FIELD

The disclosure herein relates generally to spin-orbit-torque magnetoresistive memory devices having a magnetic tunnel junction, and more particularly, to spin-orbit-torque magnetoresistive memory devices having one-time programmable ROM functions.

### INTRODUCTION

Spin-orbit-torque (SOT) magnetoresistive random access memory (MRAM) devices store information by controlling the resistance across a magnetic tunnel junction (MTJ) such that a read current through the MTJ results in a voltage drop having a magnitude that is based on the state of the MTJ stack. The resistance in an MTJ stack can be varied based on the relative magnetic states of the magnetoresistive layers within the MTJ stack. In such memory devices, there is typically a portion of the MTJ stack that has a fixed magnetic state (e.g., fixed region) and another portion that has a free magnetic state (e.g., free region) that is controlled to be in either of two possible states relative to the portion having the fixed magnetic state. Because the resistance through the MTJ stack changes based on the orientation (i.e., magnetization direction) of the free region relative to the fixed region, information can be stored in the MTJ by setting the orientation of the free region. The information may be later retrieved by sensing a resistance of the MTJ stack.

### BRIEF DESCRIPTION OF DRAWINGS

In the course of the detailed description that follows, reference will be made to the appended drawings. The drawings show different aspects of the present disclosure and, where appropriate, reference numerals illustrating like structures, components, materials, and/or elements in different figures are labeled similarly. It is understood that various combinations of the structures, components, and/or elements, other than those specifically shown, are contemplated and are within the scope of the present disclosure.

Moreover, there are many embodiments of the present disclosure described and illustrated herein. The present disclosure is neither limited to any single aspect nor embodiment thereof, nor to any combinations and/or permutations of such aspects and/or embodiments. Moreover, each of the aspects of the present disclosure, and/or embodiments thereof, may be employed alone or in combination with one or more of the other aspects of the present disclosure and/or embodiments thereof. For the sake of brevity, certain permutations and combinations are not discussed and/or illustrated separately herein; however, all permutations and combinations are considered to fall within the scope of the present inventions.

FIG. 1 depicts an exemplary SOT-MRAM array in an SOT-MRAM.

FIG. 2 depicts an exemplary one-time programmable ROM function area (e.g., antifuse) in an SOT-MRAM, according to one or more embodiments.

FIG. 3 depicts another exemplary one-time programmable ROM function area (e.g., antifuse) in an SOT-MRAM, according to one or more embodiments.

FIG. 4 depicts another exemplary one-time programmable ROM function area (e.g., antifuse) in an SOT-MRAM during a read operation, according to one or more embodiments.

FIG. 5 depicts another exemplary one-time programmable ROM function area (e.g., fuse) in an SOT-MRAM, according to one or more embodiments.

FIG. 6 depicts another exemplary one-time programmable ROM function area in an SOT-MRAM during a read operation, according to one or more embodiments.

FIG. 7 depicts another exemplary one-time programmable ROM function area (e.g., fuse) in an SOT-MRAM during a read operation, according to one or more embodiments.

FIG. 8 depicts an exemplary SOT channel arrangement, according to one or more embodiments.

FIG. 9 depicts another exemplary one-time programmable ROM function area (e.g., fuse) in an SOT-MRAM, according to one or more embodiments.

FIG. 10 depicts another exemplary one-time programmable ROM function area and an exemplary configuration for a reference resistor in an SOT-MRAM, according to one or more embodiments.

FIG. 11 depicts another exemplary one-time programmable ROM function area and an exemplary configuration for a reference resistor in an SOT-MRAM, according to one or more embodiments.

Again, there are many embodiments described and illustrated herein. The present disclosure is neither limited to any single aspect nor embodiment thereof, nor to any combinations and/or permutations of such aspects and/or embodiments. Each of the aspects of the present disclosure, and/or embodiments thereof, may be employed alone or in combination with one or more of the other aspects of the present disclosure and/or embodiments thereof. For the sake of brevity, many of those combinations and permutations are not discussed separately herein.

### DETAILED DESCRIPTION

Detailed illustrative aspects are disclosed herein. However, specific structural and functional details disclosed herein are merely representative for purposes of describing example embodiments of the present disclosure. The present disclosure may be embodied in many alternate forms and should not be construed as limited to only the embodiments set forth herein. Further, the terminology used herein is for the purpose of describing particular embodiments only and is not intended to be limiting of exemplary embodiments described herein.

When the specification makes reference to “one embodiment” or to “an embodiment,” it is intended to mean that a particular feature, structure, characteristic, or function described in connection with the embodiment being discussed is included in at least one contemplated embodiment of the present disclosure. Thus, the appearance of the phrases, “in one embodiment” or “in an embodiment,” in different places in the specification does not constitute a plurality of references to a single embodiment of the present disclosure.

As used herein, the terms “comprises,” “comprising,” or any other variation thereof, are intended to cover a non-exclusive inclusion, such that a process, method, article, or apparatus that comprises a list of elements does not include only those elements, but may include other elements not expressly listed or inherent to such process, method, article, or apparatus. The term “exemplary” is used in the sense of “example,” rather than “ideal.”

As used herein, the singular forms “a,” “an,” and “the” are intended to include the plural forms as well, unless the context clearly indicates otherwise. It also should be noted that in some alternative implementations, the features and/or steps described may occur out of the order depicted in the figures or discussed herein. For example, two steps or figures shown in succession may instead be executed substantially concurrently or may sometimes be executed in the reverse order, depending upon the functionality/acts involved. In some aspects, one or more described features or steps may be omitted altogether, or may be performed with an intermediate step therebetween, without departing from the scope of the embodiments described herein, depending upon the functionality/acts involved.

Further, the terms “first,” “second,” and the like, herein do not denote any order, quantity, or importance, but rather are used to distinguish one element from another. Similarly, terms of relative orientation, such as “top,” “bottom,” etc. are used with reference to the orientation of the structure illustrated in the figures being described. It should also be noted that all numeric values disclosed herein may have a variation of ±10% (unless a different variation is specified) from the disclosed numeric value. Further, all relative terms such as “about,” “substantially,” “approximately,” etc. are used to indicate a possible variation of ±10% (unless noted otherwise or another variation is specified).

In the interest of conciseness, conventional techniques, structures, and principles known by those skilled in the art may not be described herein, including, for example, standard magnetoresistive random access memory (MRAM) process techniques, generation of bias voltages, fundamental principles of magnetism, and basic operational principles of memory devices.

For the sake of brevity, conventional techniques related to accessing (e.g., reading or writing) memory, and other functional aspects of certain systems and subsystems (and the individual operating components thereof) may not be described in detail herein. Furthermore, the connecting lines shown in the various figures contained herein are intended to represent exemplary functional relationships and/or physical couplings between the various elements. It should be noted that many alternative or additional functional relationships or physical connections may be present in an embodiment of the subject matter.

The various embodiments presented herein are based on a magnetoresistive memory device architecture that includes an MTJ. In one embodiment, the memory device of the current disclosure may be implemented as a spin-orbit-torque (SOT) magnetoresistive random access memory (SOT-MRAM) device. In an SOT-MRAM device (e.g., a memory device including peripheral circuits and ROM areas), the magnetic state, or more particularly the magnetization direction (used interchangeably herein) of the free region in an MTJ stack may be controlled (i.e., switched) by driving a current pulse through a switching line proximate (e.g., in electrical contact with) the free region. Such a switching line may be referred to as an SOT channel. The polarity of the current pulse determines the final magnetic state of the free region (e.g., parallel or antiparallel to the fixed region). Embodiments of magnetoresistive devices described herein utilize what may be referred to as an SOT write current to switch the magnetic state of the free region in an MTJ stack. The SOT write current through an SOT channel proximate (e.g., in electrical contact with, or otherwise adjacent to) the free region may result in an injection of a spin current into the free region and a spin torque acting on the free region. The spin current may be injected into the free region in a direction perpendicular to the interface between the free region and the SOT channel. The spin torque applied to the free region by the spin current may then impact the magnetic state of the free region. The free region and the fixed region may be formed from any suitable ferromagnetic materials, such as Ni, Fe, Co, or their alloys.

In SOT-MRAM devices, the direction of the torque applied by the spin current may be dependent on the direction (or polarity) of the current flow in the SOT channel. In other words, the direction of the current flowing through the SOT channel adjacent to the free region may determine the direction of the torque that is applied to the free region. As such, the free region can be switched between two magnetically-stable states based on the torque applied by the current flowing in the proximately-positioned SOT channel in one direction or the other.

As discussed in more detail below, circuits and techniques are presented for generating an antifuse within the SOT-MRAM device with the use of shared SOT read and write lines. In this way, certain types of data may be stored without the risk of losing the data during the solder reflow process or extreme environmental conditions outside of the specified operation conditions, which was an issue with SOT-MRAM arrays. For example, the chip identification number and its operation conditions information can be stored securely, among others.

The problem with the current SOT-MRAM device designs is the ability to guarantee the operation conditions data integrity in the memory chip. There is a need for a one-time programmable ROM function area in an SOT-MRAM device.

One embodiment may include implementing a one-time programmable ROM function in an SOT-MRAM device by adding a second write current circuit along the read current path of the SOT-MRAM device. The second write current flowing through the MTJ is high enough so that the tunnel barrier of the MTJ becomes short. This creates an anti-fuse which may act as a programmed bit in a ROM fashion. The tunnel barrier may comprise insulator materials such as AlOx, MgOx, ZrOx, TiOx, HfOx, or any combinations thereof. The tunnel barrier is one example of an intermediate region disposed in between the fixed and free magnetic regions.

Another embodiment may include implementing a one-time programmable ROM function in an SOT-MRAM device by replacing the SOT channel material with low resistive material between the bits to create a specific part of the SOT channel that acts as a fuse while adding a second write current circuit along the read current path of the SOT device. The first and second write currents flowing through the SOT channel are high enough so that a disconnection occurs at a specific location within the SOT channel. This creates a fuse which may act as a programmable bit in a ROM fashion. The low resistive material part may comprise materials with lower resistivity than the other SOT channel materials and/or may have larger thickness than the other SOT channel parts.

Yet another embodiment may include implementing a one-time programmable ROM function in an SOT-MRAM device by replacing the SOT channel with low resistive material between the bits to create a specific part of the SOT channel that acts as a fuse. The write current flowing through the SOT channel is high enough so that a disconnection occurs at a specific location within the SOT channel. This creates a fuse which may act as a programmable bit in a ROM fashion.

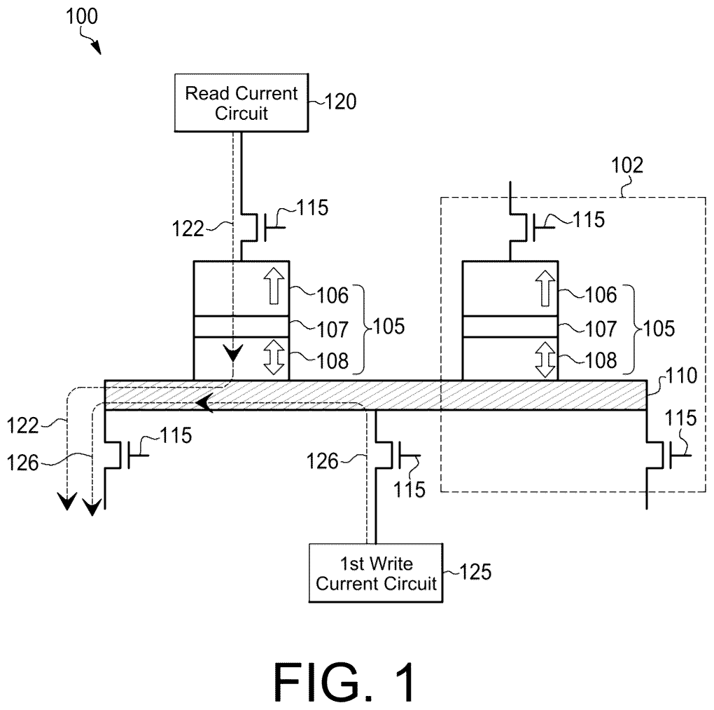

FIG. 1 illustrates an exemplary SOT-MRAM array 100 in an SOT-MRAM device (also referred to herein as simply “SOT-MRAM”). The SOT-MRAM array 100 may include a bit cell 102, an SOT channel 110, a plurality of transistors 115, a read current circuit 120, a read current 122, a write current circuit 125, and a write current 126. The SOT-MRAM array 100 may include a plurality of bit cells 102 spaced apart from each other horizontally. The bit cell 102 may include an MTJ 105, a transistor 115 coupled in series between a plurality of conductive lines. These conductive lines may allow different currents or voltages to be applied to the series circuit formed by the MTJ 105 and the transistor 115. As will be recognized by those of ordinary skill in the art, various contemplated signal lines may connect to the MTJs 105 and respective transistor 115 via any suitable electrical connection, including, but not limited to, electrodes, vias, etc.

The MTJ 105 may include a free layer 108, a tunnel barrier 107, and a fixed layer 106. The free layer 108 may be positioned adjacent to, or in electrical contact with the SOT Channel 110. The SOT channel 110 may carry the write current 126 to switch the magnetization direction of one or more free layers 108 of the MTJ 105 (e.g., write operation). The write current circuit 125 may provide the write current 126 to be driven through desired portion(s) of the SOT channel 110 controlling voltages applied to the transistors 115 and the MTJ 105. The fixed layer 106 may be positioned on an opposite side of the tunnel barrier 107 from the free layer 108. The fixed layer 106 may be connected through an interconnect (e.g., transistor 115) to the read current circuit 120. The read current circuit 120 may provide a read current 122 to read a magnetic state of the MTJ 105.

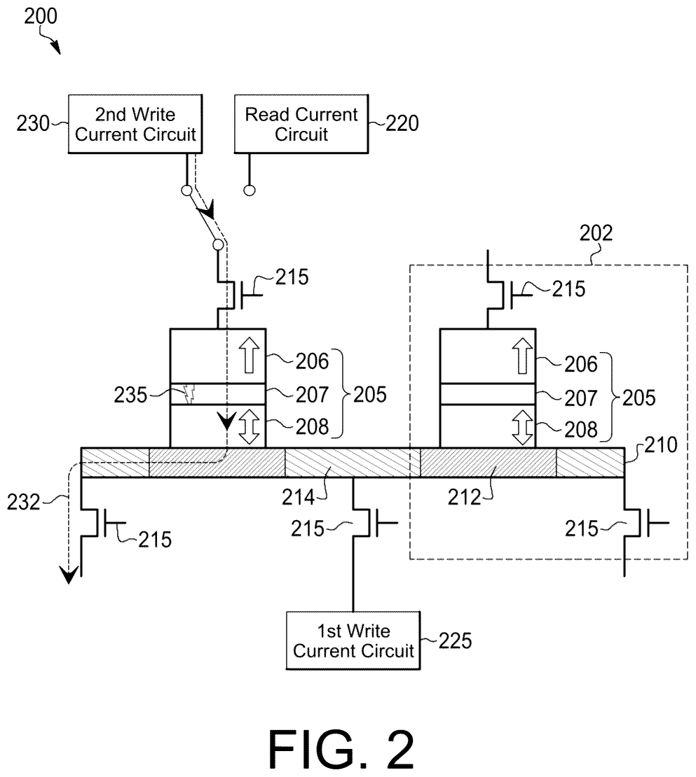

FIG. 2 illustrates an exemplary one-time programmable ROM function area (e.g., antifuse) 200 in an SOT-MRAM. Specifically, FIG. 2 illustrates the one-time programmable ROM function area 200 during a write (or programming) operation. The one-time programmable ROM function area 200 may, in some aspects, function similarly as the SOT-MRAM device 100 described above in reference to FIG. 1. However, additional components and resultant functions are available in the one-time programmable ROM function area 200 as described below. The one-time programmable ROM function area 200 may include one or more bit cells 202, an SOT channel 210, a plurality of transistors 215, a read current circuit 220, a first write current circuit 225, and a second write current circuit 230. The one or more bit cells 202 may include an MTJ 205 coupled between a transistor 215 and the SOT channel 210. The MTJ 205 may include a fixed layer 206, a tunnel barrier 207, and a free layer 208. The tunnel barrier 207 may be positioned between the fixed layer 206 and the free layer 208. The free layer 208 may be in contact with (e.g., electrical connection) the SOT channel 210. The SOT channel 210 may include one or more first portions 212 disposed adjacent the MTJs 205 (e.g., bits) and one or more second portions 214 disposed between the MTJs 205. The material for the one or more first portions 212 of the SOT channel 210 may be consistent with the existing SOT-MRAM channel material, e.g., heavy metal such as platinum (Pt), tungsten (W), or the like. The material for one or more second portions 214 of the SOT channel 210 may include a low resistive material, e.g., low resistive metal such as aluminum (Al), copper (Cu), or the like, to assist in the breakdown of the MTJ 205 and creation of an antifuse within the one-time programmable ROM function area 200.

A one-time programmable ROM function may be achieved with the addition of the second write current circuit 230 along a read current 232 path of the one-time programmable ROM function area 200. The second write current 232 that is applied by the second write current circuit 230 to flow through the MTJ 205 may be configured (e.g., high enough current) such that the tunnel barrier 207 of the MTJ 205 breaks down and becomes shorted (e.g., breakdown 235), which effectively programs the bit (e.g., antifuse). The breakdown 235 thus essentially acts as a one-time programmable ROM function. The state (e.g., programmed or unprogrammed) of each bit can be read using the read current circuit 220 and a sense circuit (not shown).

Further advantages of the embodiment illustrated in FIG. 2 may include reduced cost due to the use of the same bitcell 202 structure as those in the SOT-MRAM array (e.g., a part of the device that has a function of random-access memory array), and low voltage and safe operation compared to conventional poly resistor-based fuses. The embodiment illustrated in FIG. 2 may be combined with other embodiments in this disclosure and/or replace certain relevant aspects of the other embodiments in this disclosure.

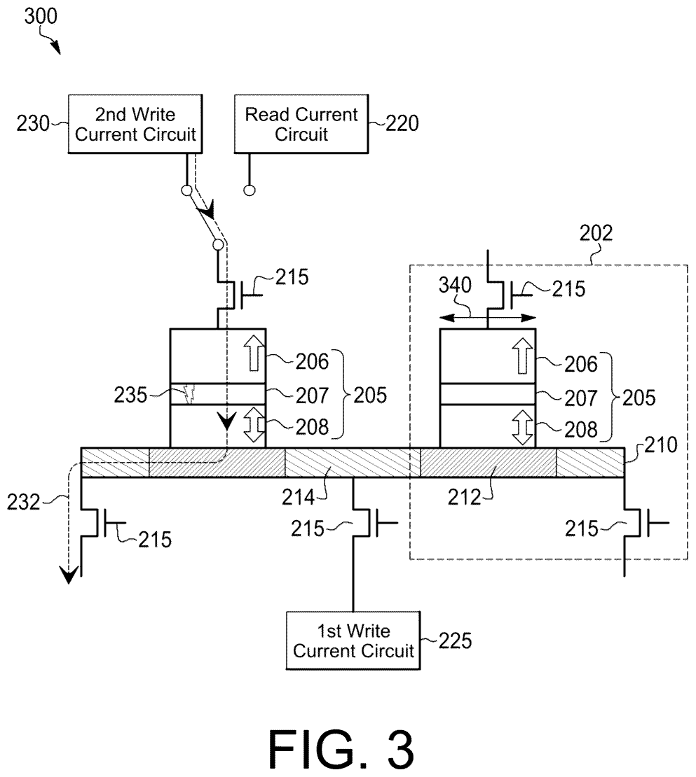

FIG. 3 illustrates another exemplary one-time programmable ROM function area (e.g., antifuse) 300 in an SOT-MRAM. Specifically, FIG. 3 illustrates the one-time programmable ROM function area 300 during a write (or programming) operation. The one-time programmable ROM function area 300 may, in some aspects, include a similar process and configuration as that described above with reference to FIG. 2. However, the embodiment shown in FIG. 3 includes additional modifications. For example, a diameter 340 of the MTJ 205 may be altered (e.g., reduced) at the location desired for the barrier breakdown 235 (e.g., antifuse). The MTJ 205 may be smaller in diameter than those in the SOT-MRAM array 100. Similar to FIG. 2, the second write current 232 that is applied by the second write current circuit 230 to flow through the MTJ 205 may be configured (e.g., high enough current) such that the tunnel barrier 207 of the MTJ 205 breaks down and becomes shorted, which effectively programs the bit (e.g., antifuse). In doing so, due to the diameter 340 of the MTJ 205 being smaller, less power may be consumed for programming and the probability of program error may be reduced because a smaller MTJ 205 may easily break down by lower current. A further advantage includes low read error probability because the resistance of the un-programmed bit becomes higher. The diameter 340 of the MTJ 205 located within the one-time programmable ROM function area 300 may be reduced without causing performance issues because there is no need to maintain the magnetization direction of the free layer 208, whereas the diameter of the MTJ 105 in the SOT-MRAM array 100 may not be as widely adjustable because the magnetization direction of the free layer 108 may need to be maintained for a significant period of time (e.g., to satisfy a long retention time), which may require a certain MTJ diameter. The embodiment illustrated in FIG. 3 may be combined with other embodiments in this disclosure and/or replace certain relevant aspects of the other embodiments in this disclosure.

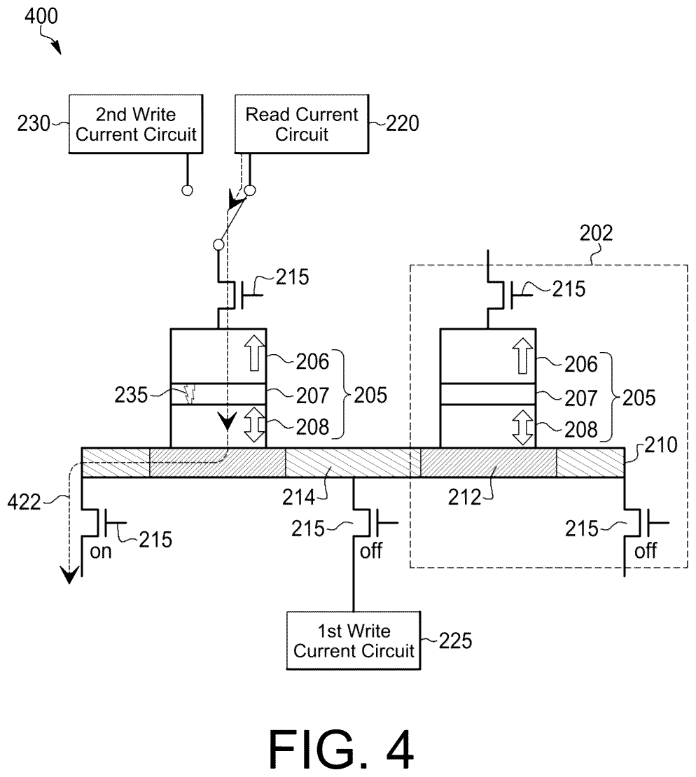

FIG. 4 illustrates an exemplary one-time programmable ROM function area (e.g., antifuse) 400 in an SOT-MRAM during a read operation. As would be apparent to one of ordinary skill in the art, the read operation, as described below, may be applicable to other embodiments of this disclosure (e.g., the areas 200 and 300). During a read operation, a read current 422 flows from the read current circuit 220 into the bitcell 202 (e.g., transistor 215 and MTJ 205). The read current 422 continues flowing into the SOT channel 210 and exits through a transistor 215, which may be in the “on” position. In the read operation, the MTJ 205 resistance may be compared with a reference resistor (not shown).

To retrieve the information from read-only memory (ROM), the resistance of the MTJ stack or the resistance of the SOT channel may be compared with that of the reference resistor. For the read operation in the conventional MRAM array, MTJs are often used for the reference resistor. If an MTJ is used as a reference resistor (e.g., an MTJ reference resistor) for a ROM function, a resistance value of the MTJ reference resistor may be changed through switching from AP to P or P to AP by applying an external magnetic field and by exposing to a reflow temperature, which may cause a reading error of the ROM function. In addition, MTJs may sometimes be defective, for example shorted, which may also cause a reading error of the ROM function. If a reference resistor is made of poly-Si, a resistance value may not change by applying an external magnetic field and/or by exposure to a reflow temperature. This may cause a secure and permanent one-time programmable ROM function without the concern of losing data during the solder reflow process or extreme environmental conditions outside of the specified operation conditions. Materials used for this secure reference resistance may include, for example, poly-Si resistor, diffusion resistor, metal resistor, or the like. By using these stable materials, the reference resistor may become less defective than conventional MTJs and may cause lower error rate for ROM functions.

Thus, as explained above, the reference resistor used for the ROM function may not be an MTJ but a resistor whose resistance is not changed by applying an external magnetic field and/or by exposing it to a reflow temperature. The reference resistor may include a poly-Si resistor, a diffusion resistor, metal resistor, or the like. When a short occurs (e.g., breakdown 235), the MTJ 205 resistance is altered and the MTJ 205 may be read as programmed (e.g., short). Advantageously, providing the one-time programmable ROM function area 400 in the SOT-MRAM may enable storage of certain data (e.g., chip identification number, operation conditions data, etc.) securely and permanently.

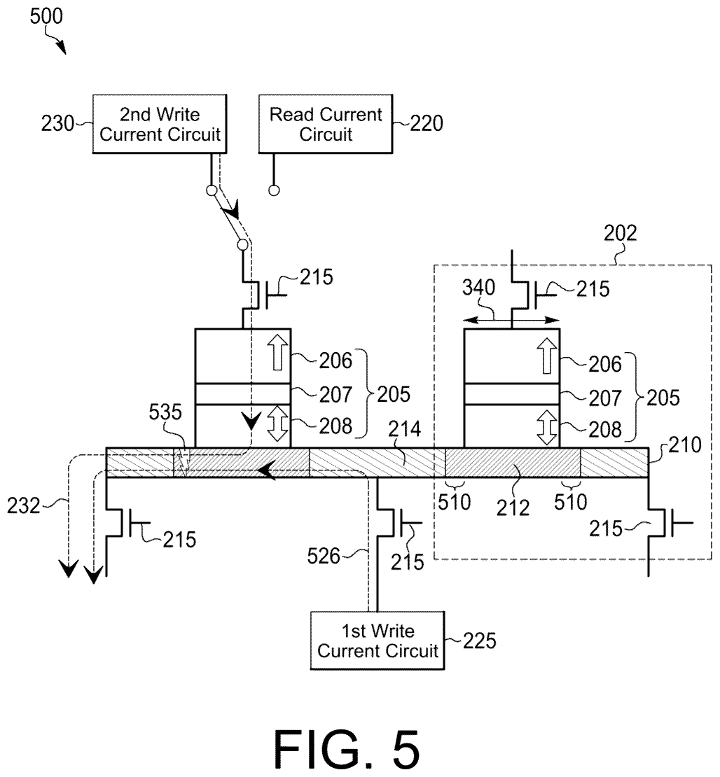

FIG. 5 illustrates an exemplary one-time programmable ROM function area (e.g., fuse) 500 in an SOT-MRAM. Specifically, FIG. 5 illustrates the one-time programmable ROM function area 500 during a write (or programming) operation. As shown in FIG. 5 and would be apparent to one of ordinary skill in the art, the one-time programmable ROM function area 500 may, in some aspects, include a similar process and configuration as those described above with reference to FIGS. 2-3. However, the embodiment shown in FIG. 5 includes additional modifications. For example, during the write operation, in addition to applying the second write current 232 by the second write current circuit 230, a first write current 526 is also applied using a first write current circuit 225. The applied currents may be high enough such that the SOT channel 210 becomes disconnected and “open” (e.g., breakdown 535) due to the high enough current flowing through the SOT channel 210. To aid in this process, one or more portions (e.g., one or more second portions 214) of the SOT channel 210 may include a low resistive material (e.g., Al, Cu, or the like) between the bits to create a specific location within the SOT channel 210 that acts as a fuse (e.g., breaks down when the currents 232 and 526 are applied). The specific parts of the SOT channel 210 underneath the MTJ 205 and extending beyond the MTJ 205 stack (e.g., the portions of the SOT channel disposed within length 510 (e.g., Lᵥ) denoted in FIG. 5 with respect to the one or more first portions 212 of the SOT channel 210) may be vulnerable to breakdown 535 due to high resistance and excessive Joule heating when a write current flows, thus creating a fuse. One embodiment may include the length 510 between approximately 5 and approximately 50 nm or approximately 10% and approximately 50% of the MTJ 205 stack diameter 340. One embodiment may include the length 510 of approximately 10 nm or 20% of the MTJ 205 stack diameter (e.g., 340).

As explained above, to program the bit cell, the first write current 526 and the second write current 232 may be controlled by the first write current circuit 225 and second write current circuit 230, respectively, and may flow sufficiently high to generate a disconnect in the SOT channel 210 and make the channel open (e.g., breakdown 535). In one embodiment, the second write current 232 may be configured to be low enough to maintain the tunnel barrier 207 in the MTJ 205. To read the bit cell, the read current circuit 220 and a sense circuit (now shown) may be used to determine the SOT channel 210 resistance, the channel being open (e.g., programmed) or closed (e.g., unprogrammed).

The advantages of the embodiment illustrated in FIG. 5 may include those described with respect to FIG. 2. A further advantage may include, when combined with the embodiment illustrated in FIG. 2, a bit cell may be capable of storing three states, including short, normal resistance, and open. The embodiment illustrated in FIG. 5 may be combined with other embodiments in this disclosure and/or replace certain relevant aspects of the other embodiments in this disclosure.

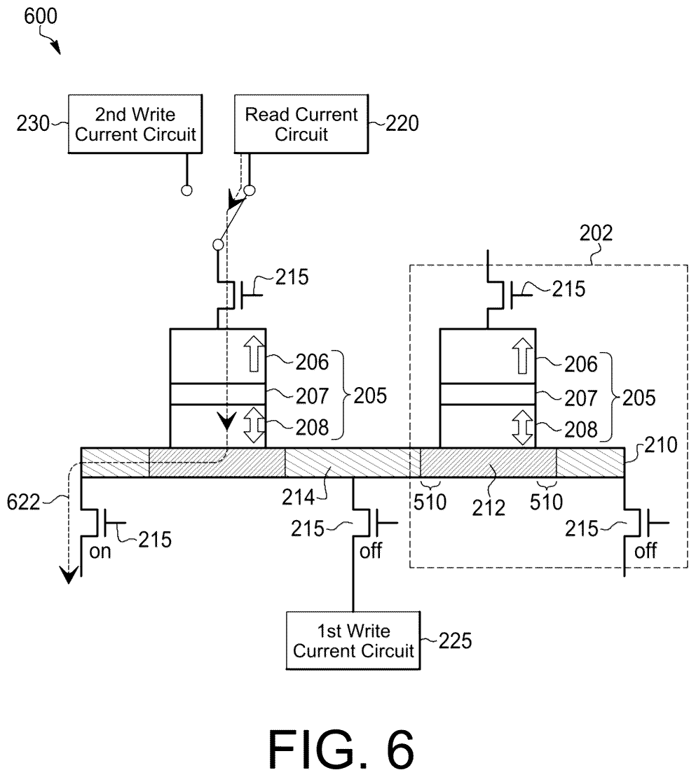

FIG. 6 illustrates an exemplary one-time programmable ROM function area 600 in an SOT-MRAM during a read operation. Specifically, FIG. 6 depicts a read operation when the SOT channel 210 is in a “closed” or an “unprogrammed” state. As would be apparent to one of ordinary skill in the art, the read operation, as described below, may be applicable to other embodiments of this disclosure (e.g., the areas 200, 300, and 500). During a read operation, for a read current 622 for an unprogrammed bit, the read current 622 flows from the read current circuit 220 into the bitcell 202 (e.g., transistor 215 and MTJ 205). The read current 622 continues flowing into the SOT channel 210 and exits through a transistor 215, which may be in the “on” position. In the read operation, the MTJ 205 resistance may be compared with a reference resistor (not shown). The reference resistor may not be an MTJ but a resistor whose resistance is not changed by applying an external magnetic field and/or by exposing it to a reflow temperature. The reference resistor may include a poly-Si resistor, a diffusion resistor, a metal resistor, or the like.

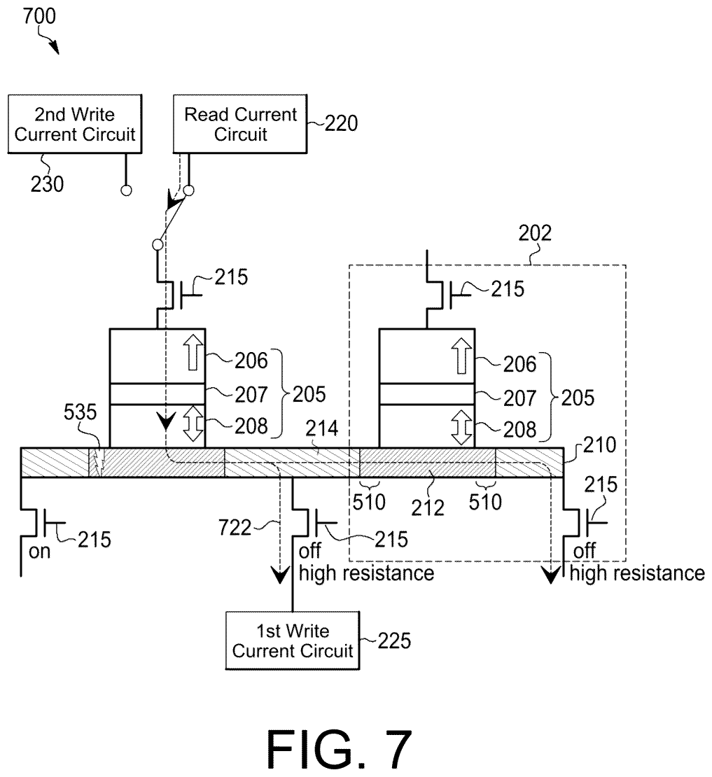

FIG. 7 illustrates an exemplary one-time programmable ROM function area 700 in an SOT-MRAM during a read operation. Specifically, FIG. 7 depicts a read operation when the SOT channel 210 is in an “open” or a “programmed” state due do the breakdown 535 in the SOT channel 210. During a read operation, for a read current 722 for a programmed bit, the read current 722 flows from the read current circuit 220 into the bitcell 202 (e.g., transistor 215 and MTJ 205). The read current 722 continues flowing into the SOT channel 210 and exits through one or more transistors 215, which may be in the “off” position. In one embodiment, the one or more transistors 215 may include high resistance states. In the read operation, the MTJ 205 resistance may be compared with a reference resistor (not shown). The reference resistor may not be an MTJ but a resistor whose resistance is not changed by applying an external magnetic field and/or by exposing it to a reflow temperature. The reference resistor may include a poly-Si resistor, a diffusion resistor, a metal resistor, or the like.

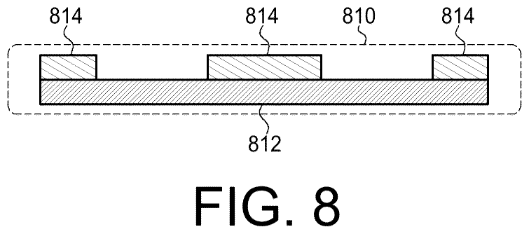

FIG. 8 illustrates an alternative method to using a low resistive material for portions (e.g., the one or more second portions 214) of the SOT channel 210, which is discussed above with respect to FIG. 5. Instead of having alternating segments of first portions 212 and second portions 214 horizontally in the SOT channel 210, the alternative SOT channel 810 may include a first portion 812 that extends continually while one or more second portions 814 abut the first portion 812 at regular intervals. Therefore, instead of replacing portions of the SOT channel 810 with low resistive materials (e.g., second portion 214), a metal line (e.g., one or more second portions 814) touching the top or bottom of the SOT channel material (e.g., first portion 812) may be formed between the bits, reducing the line resistance between the bits. Placing the metal line (e.g., one or more second portions 814) at these locations may reduce overall Joule heating while improving reliability and energy efficiency. For example, the first portion 812 may comprise thin tungsten (W) layer, and the second portion 814 may comprise thick aluminum (Al) or copper (Cu) layer. In another embodiment, the first portion 812 may be thin ferromagnetic metal with in-plane magnetization comprising cobalt (Co), iron (Fe), boron (B), cobalt-iron (CoFe), cobalt-iron-boron (CoFeB), or their alloys, and the second portion 814 may be thick antiferromagnet comprising platinum-manganese (PtMn) or iridium-manganese (IrMn). In the latter case, the exchange bias from the second portion 814 to the first portion 812 may align the magnetization direction of the first portion 812 to one direction across the whole MRAM array, which may achieve a precise and uniform field free switching for a perpendicular free layer. The embodiment illustrated in FIG. 8 may be combined with other embodiments in this disclosure and/or replace certain relevant aspects of the other embodiments in this disclosure.

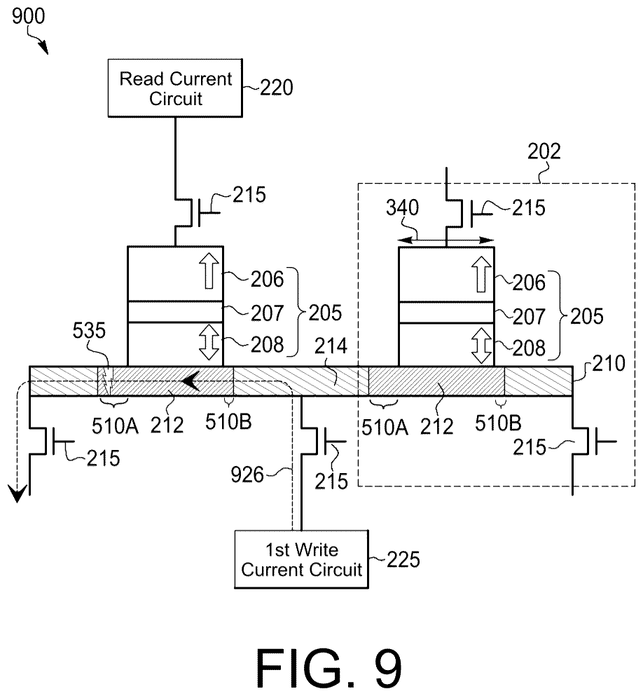

FIG. 9 illustrates an exemplary one-time programmable ROM function area (e.g., fuse) 900 in an SOT-MRAM. Specifically, FIG. 9 illustrates the one-time programmable ROM function area 900 during a write (or programming) operation. The operations of the embodiment illustrated in FIG. 9 are substantially similar to those of FIG. 5, but the one-time programmable ROM function area 900 in FIG. 9 does not include a second write current circuit and applies certain modifications to the SOT channel 210. To program the bit cell, the first write current 926 that is sufficiently high enough (e.g., a higher or stronger current than ones used in typical write operations to an SOT-MRAM array) to create a disconnect in the SOT channel 210 is applied through the SOT channel 210 by the first write current circuit 225, making the SOT channel 210 open (e.g., fuse). To aid in this process, one or more portions (e.g., one or more second portions 214) of the SOT channel 210 may include a low resistive material (e.g., Al, Cu, or the like) between the bits to create a specific location within the SOT channel 210 that acts as a fuse (e.g., breaks down when the first write current 926 is applied). The first portion 212 of the SOT channel 210 material underneath the MTJ 205 extending laterally beyond the MTJ 205 stack may be vulnerable due to high resistance and excessive Joule heating when a write current flows, thus creating a fuse. In one embodiment, a vulnerable portion may be created within the SOT channel 210 beyond one end of the MTJ 205 stack, which may become more easily disconnect-able via high current. In one embodiment, the vulnerable portion of the SOT channel 210 beyond one end of the MTJ 205 stack may be longer (laterally in FIG. 9) and/or thinner (vertically in FIG. 9) than the portion beyond the opposite end of the MTJ 205 stack. Therefore, the length 510A of the vulnerable portion may be longer than the length 510B of the portion on the other end. The length 510A may be between approximately 5 and approximately 50 nm, or approximately 10% and approximately 50% of the MTJ 205 stack diameter 340. The breakdown 535 at the vulnerable portion of the SOT channel 210 caused by the high current may act as a ROM function programming a bit cell at the location of the breakdown 535. To read the bit cell, a read current circuit (not shown) and a sense circuit (not shown) may be used to determine the SOT channel 210 resistance, the SOT channel 210 being open (e.g., programmed) or closed (e.g., un-programmed). The advantages of the embodiment illustrated in FIG. 9 include those described with respect to FIG. 2. The embodiment illustrated in FIG. 9 may be combined with other embodiments in this disclosure and/or replace certain relevant aspects of the other embodiments in this disclosure.

As depicted in FIG. 5, the first write current 526 plus the second write current 232 (e.g., the first write current 526 and the second write current 232 combined) may be high or strong enough to create a disconnect in the SOT channel 210, while the second write current 232 is sufficiently low enough to maintain the barrier in the MTJ 205 stack and the first write current 526 is sufficiently low enough to maintain the continuity of the SOT channel 210. One embodiment may include the first write current 526 being higher than the second write current 232. Another embodiment may include the second write current 232 being higher than the first write current 526. As depicted in FIG. 9, the first write current 926 is sufficiently high enough to create a disconnect (e.g., breakdown 535) in the SOT channel 210 while the first write current 926 is sufficiently low enough so that the barrier in the MTJ 205 is not impacted by the first write current 926.

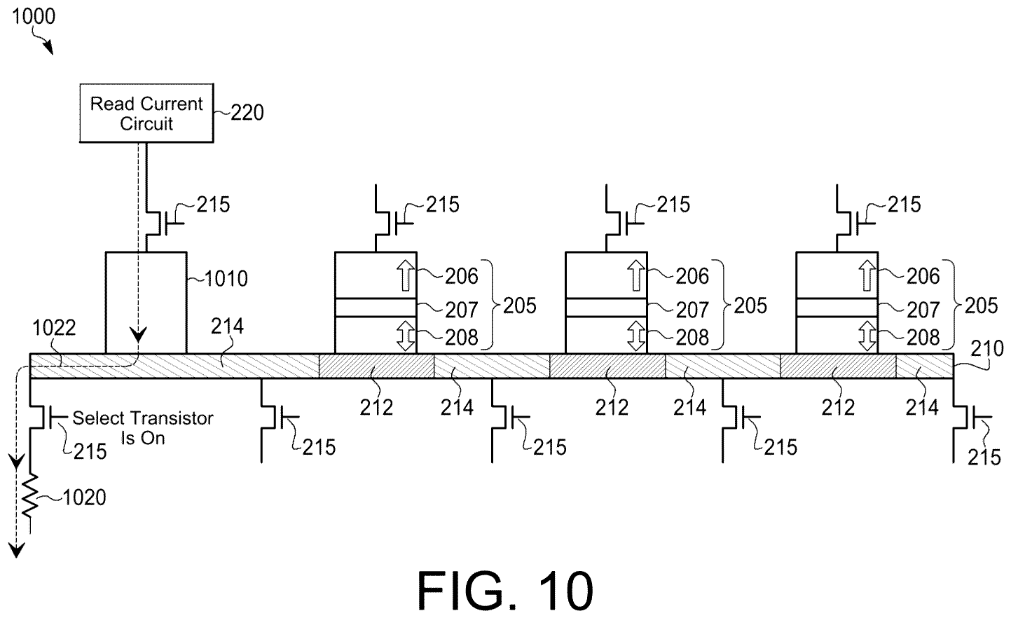

FIG. 10 illustrates an exemplary one-time programmable ROM function area 1000 in an SOT-MRAM. The one-time programmable ROM function area 1000 may include a similar process and configuration as described above with reference to any of FIGS. 2-9. However, the area 1000 shown in FIG. 10 includes additional modifications, including a reference resistor in a read current circuit. In one embodiment, a metal via 1010 connected to a transistor 215 and the read current circuit 220 may be implemented on an appropriate location of the SOT channel 210. The metal via 1010 may be included within the MTJ array of the area 1000. The portion of the SOT channel 210 on which the via 1010 is positioned may comprise a low resistive material similar to that of the second portion 214. Based on this, the portion of the SOT channel 210 on which the via 1010 is positioned is denoted as 214 in FIG. 10. This portion of the SOT channel 210 may further be connected to a select transistor 215, which may in turn be connected to a reference resistor 1020. A read current 1022 may be generated by the read current circuit 220 and may flow through the transistor 215, the metal via 101, the select transistor 215, and the reference resistor 1020, when the select transistor 215 coupled to the reference resistor 1020 is in the “on” position. In a read operation, the resistance of an appropriate bit cell (e.g., MTJ 205) or a corresponding portion of the SOT channel 210 may be compared with the resistance of the reference resistor 1020, to determine the output state. The resistance of the reference resistor 1020 will remain stable, as it will not be affected by an external magnetic field and/or by exposure to reflow temperature. The reference resistor 1020 may include a poly-Si resistor, a diffusion resistor, a metal resistor, or the like.

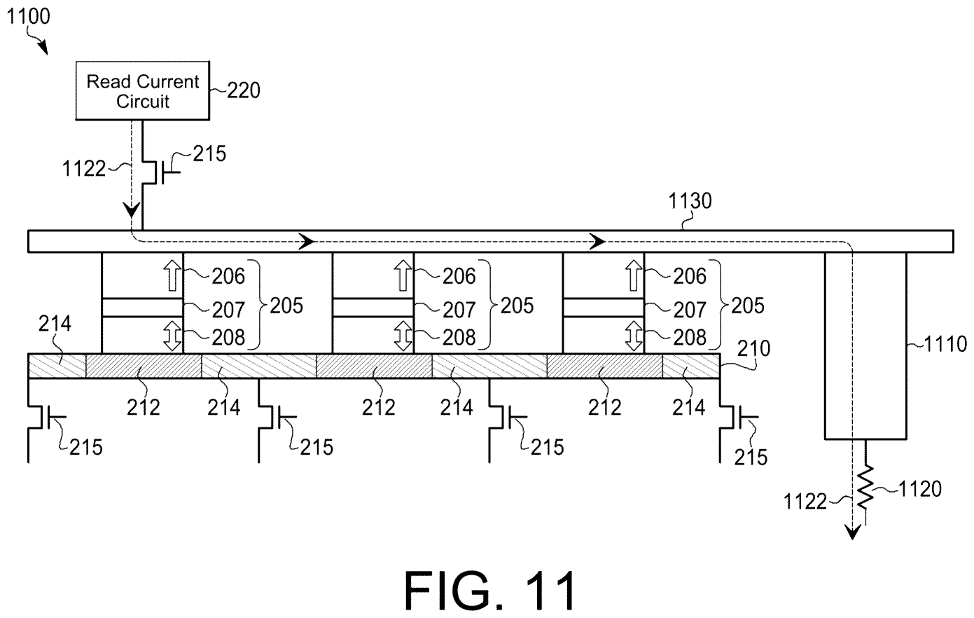

FIG. 11 illustrates an exemplary one-time programmable ROM function area 1100 in an SOT-MRAM. The one-time programmable ROM function area 1100 may include a similar process and configuration as described above with reference to any of FIGS. 2-9. However, the area 1100 shown in FIG. 11 includes additional modifications. In one embodiment, a metal short 1130 may be connected across the top of the MTJs 205 in the MTJ array of the area 1100. Specifically, the metal short 1130 may be connected across the fixed layers 206 of the MTJs 205 in the MTJ array of the area 1100. The metal short 1130 may be connected to the read current circuit 220 by way of a transistor 215. The metal short 1130 may further be connected to a metal via 1110 that is outside the MTJ array and that is connected to a reference resistor 1120. A read current 1122 may be generated by the read current circuit 220 and may flow through the transistor 215, the metal short 1130, the metal via 1110, and the reference resistor 1120. In a read operation, the resistance of an appropriate bit cell (e.g., MTJ 205) or a corresponding portion of the SOT channel 210 may be compared with the resistance of the reference resistor 1120, to determine the output state. The resistance of the reference resistor 1120 will remain stable, as it will not be affected by an external magnetic field and/or by exposure to reflow temperature. The reference resistor 1120 may include a poly-Si resistor, a diffusion resistor, a metal resistor, or the like.

In one embodiment, the present disclosure is drawn to a magnetoresistive memory, including: a plurality of magnetoresistive memory devices, wherein each magnetoresistive device includes a fixed magnetic region, a free magnetic region, and an intermediate region disposed in between the fixed and free magnetic regions; a spin-orbit-torque (SOT) channel, wherein the SOT channel is in contact with the free magnetic regions of the plurality of magnetoresistive memory devices; a write circuit configured to apply a write current through at least one magnetoresistive memory device of the plurality of magnetoresistive memory devices and the SOT channel, wherein the current is configured to generate a short in at least one magnetoresistive memory device as a one-time programmable read-only memory (ROM) function.

Various aspects of the present disclosure may also include: wherein the write current is sufficiently high enough to generate a short in the at least one magnetoresistive memory device; the magnetoresistive memory further comprising a read circuit configured to determine the short in the at least one magnetoresistive memory device; and wherein at least a portion of the SOT channel includes low resistive material.

In another embodiment, the present disclosure is drawn to a magnetoresistive memory, including: a plurality of magnetoresistive memory devices, wherein each magnetoresistive device includes a fixed magnetic region, a free magnetic region, and an intermediate region disposed in between the fixed and free magnetic regions; a spin-orbit-torque (SOT) channel, wherein the SOT channel is in contact with the free magnetic regions of the plurality of magnetoresistive memory devices; a first write circuit configured to apply a first write current through the SOT channel; and a second write circuit configured to apply a second write current through at least one magnetoresistive memory device of the plurality of magnetoresistive memory devices and the SOT channel, wherein the first current is configured to change a magnetization direction of at least one free magnetic region, and wherein the second current is configured to generate a short in at least one magnetoresistive memory device as a one-time programmable read-only memory (ROM) function.

Various aspects of the present disclosure may also include: wherein the second write current is sufficiently high enough to generate the short in the at least one magnetoresistive memory device; the magnetoresistive memory further comprising a read circuit configured to determine the short in the at least one magnetoresistive memory device; the magnetoresistive memory further comprising a reference resistor in the read circuit, wherein the resistance value is not changed by applying an external magnetic field or by exposure to a reflow temperature; wherein the at least one magnetoresistive memory device is in a ROM function area and one or more other magnetoresistive memory devices of the plurality of magnetoresistive memory devices are in a non-ROM function area, wherein a diameter of the at least one magnetoresistive memory device is smaller than a diameter of the one or more other magnetoresistive memory devices; and wherein at least a portion of the SOT channel includes low resistive material.

In yet another embodiment, the present disclosure is drawn to a magnetoresistive memory, including: a plurality of magnetoresistive memory devices, wherein each magnetoresistive device includes a fixed magnetic region, a free magnetic region, and an intermediate region disposed in between the fixed and free magnetic regions; a spin-orbit-torque (SOT) channel, wherein the SOT channel is in contact with the free magnetic regions of the plurality of magnetoresistive memory devices and, wherein the SOT channel includes a first set of segments disposed between the plurality of magnetoresistive memory devices and a second set of segments disposed adjacent the plurality of magnetoresistive memory devices; a first write circuit configured to apply a first write current through the SOT channel; and a second write circuit configured to apply a second write current through at least one magnetoresistive memory device of the plurality of magnetoresistive memory devices and the SOT channel, wherein the first current and the second current applied through the SOT channel generate a disconnection at at least one of the second set of segments of the SOT channel as a one-time programmable read-only memory (ROM) function.

Various aspects of the present disclosure may also include: wherein the first set of segments of the SOT channel includes a low resistive material; wherein each of the second set of segments of the SOT channel extends beyond a diameter of the adjacent magnetoresistive memory device; wherein the first write current and the second write current are sufficiently high enough to generate the disconnection; wherein each of the second set of segments of the SOT channel extends beyond a diameter of the adjacent magnetoresistive memory device by a range of at least one of between approximately 5 nm and approximately 50 nm and between approximately 10% and approximately 50% of the diameter of the adjacent magnetoresistive memory device; wherein the first write current is sufficiently high enough to generate the disconnection; wherein each of the second set of segments of the SOT channel extends beyond a diameter of the adjacent magnetoresistive memory device further on one side of the adjacent magnetoresistive memory device than the other; and wherein each of the second set of segments of the SOT channel has a first portion that extends beyond one side of the adjacent magnetoresistive memory device and a second portion that extends beyond the other side of the adjacent magnetoresistive memory device, wherein a thickness of the first portion is smaller than a thickness of the second portion.

In yet another embodiment, the present disclosure is drawn to a magnetoresistive memory, including: a plurality of magnetoresistive memory devices, wherein each magnetoresistive device includes a fixed magnetic region, a free magnetic region, and an intermediate region disposed in between the fixed and free magnetic regions; a spin-orbit-torque (SOT) channel, wherein the SOT channel is in contact with the free magnetic regions of the plurality of magnetoresistive memory devices; a metal layer including a plurality of metal segments, wherein the plurality of metal segments are disposed between the plurality of magnetoresistive memory devices and on the SOT channel; a first write circuit configured to apply a first write current through the SOT channel; and a second write circuit configured to apply a second write current through at least one magnetoresistive memory device of the plurality of magnetoresistive memory devices and the SOT channel, wherein the first current and the second current applied through the SOT channel generate a disconnection at a portion of the SOT channel proximate the at least one magnetoresistive memory device as a one-time programmable read-only memory (ROM) function.

In yet another embodiment, the present disclosure is drawn to a magnetoresistive memory, including: a plurality of magnetoresistive memory devices, wherein each magnetoresistive device includes a fixed magnetic region, a free magnetic region, and an intermediate region disposed in between the fixed and free magnetic regions; a spin-orbit-torque (SOT) channel, wherein the SOT channel is in contact with the free magnetic regions of the plurality of magnetoresistive memory devices; a first write circuit configured to apply a first write current through the SOT channel; and a second write circuit configured to apply a second write current through at least one magnetoresistive memory device of the plurality of magnetoresistive memory devices and the SOT channel, wherein the first current is configured to change a magnetization direction of at least one free magnetic region, wherein the second current is configured to generate a short in at least one magnetoresistive memory device as a one-time programmable read-only memory (ROM) antifuse function, and wherein at least one of the first current or the second current is configured to generate a disconnection at a section of the SOT channel as a one-time programmable read-only memory (ROM) fuse function.

Other embodiments of the disclosure will be apparent to those skilled in the art from consideration of the specification and practice of the embodiment(s) disclosed herein. It is intended that the specification and examples be considered as exemplary only, with a true scope and spirit of the embodiment(s) being indicated by the following claims.

While exemplary embodiments have been presented above, it should be appreciated that many variations exist. Furthermore, while the description includes references to MRAM devices, the teachings may be applied to other memory devices having different architectures in which the same concepts can be applied. Thus, the particular embodiments disclosed above are illustrative only and should not be taken as limitations, as the embodiments may be modified and practiced in different but equivalent manners apparent to those skilled in the art having the benefit of the teachings herein. Accordingly, the foregoing description is not intended to limit the disclosure to the particular form set forth, but on the contrary, is intended to cover such alternatives, modifications and equivalents as may be included within the spirit and scope of the inventions as defined by the appended claims so that those skilled in the art should understand that they can make various changes, substitutions and alterations without departing from the spirit and scope of the inventions in their broadest form.

The foregoing description of the inventions has been described for purposes of clarity and understanding. It is not intended to limit the inventions to the precise form disclosed. Various modifications may be possible within the scope and equivalence of the application.

We claim:

1. A magnetoresistive memory, comprising:
a plurality of magnetoresistive memory devices, wherein each magnetoresistive device includes a fixed magnetic region, a free magnetic region, and an intermediate region disposed between the fixed and free magnetic regions;
a spin-orbit-torque (SOT) channel, wherein the SOT channel is in contact with the free magnetic regions of the plurality of magnetoresistive memory devices; and
a write circuit configured to apply a write current through at least one magnetoresistive memory device of the plurality of magnetoresistive memory devices and the SOT channel,
wherein the write current is configured to generate a short in at least one magnetoresistive memory device as a one-time programmable read-only memory (ROM) function.

2. The magnetoresistive memory of claim 1, wherein the write current is sufficiently high enough to generate a short in the at least one magnetoresistive memory device.

3. The magnetoresistive memory of claim 1, further comprising a read circuit configured to determine the short in the at least one magnetoresistive memory device.

4. The magnetoresistive memory of claim 1, wherein at least a portion of the SOT channel includes low resistive material.

5. A magnetoresistive memory, comprising:
a plurality of magnetoresistive memory devices, wherein each magnetoresistive device includes a fixed magnetic region, a free magnetic region, and an intermediate region disposed between the fixed and free magnetic regions;
a spin-orbit-torque (SOT) channel, wherein the SOT channel is in contact with the free magnetic regions of the plurality of magnetoresistive memory devices;
a first write circuit configured to apply a first write current through the SOT channel; and
a second write circuit configured to apply a second write current through at least one magnetoresistive memory device of the plurality of magnetoresistive memory devices and the SOT channel,
wherein the first current is configured to change a magnetization direction of at least one free magnetic region, and wherein the second current is configured to generate a short in at least one magnetoresistive memory device as a one-time programmable read-only memory (ROM) function.

6. The magnetoresistive memory of claim 5, wherein the second write current is sufficiently high enough to generate the short in the at least one magnetoresistive memory device.

7. The magnetoresistive memory of claim 5, further comprising a read circuit configured to determine the short in the at least one magnetoresistive memory device.

8. The magnetoresistive memory of claim 7, further comprising a reference resistor in the read circuit, wherein a resistance of the reference resistor is not changed by applying an external magnetic field or by exposure to a reflow temperature.

9. The magnetoresistive memory of claim 5, wherein the at least one magnetoresistive memory device is in a ROM function area and one or more other magnetoresistive memory devices of the plurality of magnetoresistive memory devices are in a non-ROM function area, wherein a diameter of the at least one magnetoresistive memory device is smaller than a diameter of the one or more other magnetoresistive memory devices.

10. The magnetoresistive memory of claim 5, wherein at least a portion of the SOT channel includes low resistive material.

11. A magnetoresistive memory, comprising:
a plurality of magnetoresistive memory devices, wherein each magnetoresistive device includes a fixed magnetic region, a free magnetic region, and an intermediate region disposed between the fixed and free magnetic regions;
a spin-orbit-torque (SOT) channel, wherein the SOT channel is in contact with the free magnetic regions of the plurality of magnetoresistive memory devices and, wherein the SOT channel includes a first set of segments disposed between the plurality of magnetoresistive memory devices and a second set of segments disposed adjacent the plurality of magnetoresistive memory devices;
a first write circuit configured to apply a first write current through the SOT channel; and
a second write circuit configured to apply a second write current through at least one magnetoresistive memory device of the plurality of magnetoresistive memory devices and the SOT channel,
wherein the first current and the second current applied through the SOT channel generate a disconnection at at least one of the second set of segments of the SOT channel as a one-time programmable read-only memory (ROM) function.

12. The magnetoresistive memory of claim 11, wherein the first set of segments of the SOT channel includes a low resistive material.

13. The magnetoresistive memory of claim 11, wherein each of the second set of segments of the SOT channel extends beyond a diameter of the adjacent magnetoresistive memory device.

14. The magnetoresistive memory of claim 11, wherein the first write current and the second write current are sufficiently high enough to generate the disconnection.

15. The magnetoresistive memory of claim 11, wherein each of the second set of segments of the SOT channel extends beyond a diameter of the adjacent magnetoresistive memory device by a range of at least one of between approximately 5 nm and approximately 50 nm and between approximately 10% and approximately 50% of the diameter of the adjacent magnetoresistive memory device.

16. The magnetoresistive memory of claim 11, wherein the first write current is sufficiently high enough to generate the disconnection.

17. The magnetoresistive memory of claim 11, wherein each of the second set of segments of the SOT channel extends beyond a diameter of the adjacent magnetoresistive memory device further on one side of the adjacent magnetoresistive memory device than the other.

18. The magnetoresistive memory of claim 11, wherein each of the second set of segments of the SOT channel has a first portion that extends beyond one side of the adjacent magnetoresistive memory device and a second portion that extends beyond the other side of the adjacent magnetoresistive memory device, wherein a thickness of the first portion is smaller than a thickness of the second portion.

19. A magnetoresistive memory, comprising:
a plurality of magnetoresistive memory devices, wherein each magnetoresistive device includes a fixed magnetic region, a free magnetic region, and an intermediate region disposed between the fixed and free magnetic regions;
a spin-orbit-torque (SOT) channel, wherein the SOT channel is in contact with the free magnetic regions of the plurality of magnetoresistive memory devices;
a metal layer comprising a plurality of metal segments, wherein the plurality of metal segments are disposed between the plurality of magnetoresistive memory devices and on the SOT channel;
a first write circuit configured to apply a first write current through the SOT channel; and
a second write circuit configured to apply a second write current through at least one magnetoresistive memory device of the plurality of magnetoresistive memory devices and the SOT channel,
wherein the first current and the second current applied through the SOT channel generate a disconnection at a portion of the SOT channel proximate the at least one magnetoresistive memory device as a one-time programmable read-only memory (ROM) function.

20. A magnetoresistive memory, comprising:
a plurality of magnetoresistive memory devices, wherein each magnetoresistive device includes a fixed magnetic region, a free magnetic region, and an intermediate region disposed between the fixed and free magnetic regions;
a spin-orbit-torque (SOT) channel, wherein the SOT channel is in contact with the free magnetic regions of the plurality of magnetoresistive memory devices;
a first write circuit configured to apply a first write current through the SOT channel; and
a second write circuit configured to apply a second write current through at least one magnetoresistive memory device of the plurality of magnetoresistive memory devices and the SOT channel,
wherein the first current is configured to change a magnetization direction of at least one free magnetic region,
wherein the second current is configured to generate a short in at least one magnetoresistive memory device as a one-time programmable read-only memory (ROM) antifuse function, and
wherein at least one of the first current or the second current is configured to generate a disconnection at a section of the SOT channel as a one-time programmable read-only memory (ROM) fuse function.
